(19) United States
(12) Patent Application Publication
(10) Pub. No.: US 2010/0278694 A1
(43) Pub. Date: Nov. 4, 2010

(54) SILICON BIOSENSOR AND MANUFACTURING METHOD THEREOF

(75) Inventors: Chul Huh, Daejeon (KR); Kyung Hyun Kim, Daejeon (KR); Jong Cheol Hong, Daejeon (KR); Hyun Sung Ko, Daejeon (KR); Wan Joong Kim, Gyunggi-do (KR); Gun Yong Sung, Daejeon (KR); Seon Hee Park, Daejeon (KR)

Correspondence Address: LADAS & PARRY LLP, 224 SOUTH MICHIGAN AVENUE, SUITE 1600, CHICAGO, IL, 60604, US

(73) Assignee: Electronics and Telecommunications Research Institute

(21) Appl. No.: 12/746,247

(22) PCT Filed: Jun. 20, 2008
(86) PCT No.: PCT/KR08/03543

§ 371 Date: Jun. 4, 2010

(30) Foreign Application Priority Data
Dec. 10, 2007 (KR) 10-2007-0127882

(51) Int. Cl. G01N 21/00; H01L 21/70

(52) U.S. Cl. 422/69; 438/24; 257/E21.532; 438/49

(57) ABSTRACT

A silicon biosensor and a manufacturing method thereof is provided, the silicon biosensor includes: a light source performing self emission a light detector generating a photoelectric current corresponding to an amount of incident light an optical fiber transmitting the light from the light source to the light detector and a micro fluidic channel adjusting an optical transmission rate of the optical fiber according to an antibody-antigen reaction when the antibody-antigen reaction occurs. The silicon biosensor can be easily integrated or bonded with a silicon electronic device, so that it is possible to manufacture the biosensor with a low price, under mass production.

### TECHNICAL FIELD

The present invention relates to a biosensor, and more particularly, to a silicon biosensor and a manufacturing method thereof, which can detect a biomaterial by integrating a light source and a light detector on a silicon substrate.

### BACKGROUND ART

A biosensor is constructed with a bioreceptor and a signal transducer to selectively sense a to-be-analyzed material. As the bioreceptor, there are an enzyme, an antibody, an antigen, a cell, and a deoxyribonucleic acid (DNA) and the like, which selectively react and link with a particular material. As a method of converting signals, there are various physicochemical methods such as an electrochemical method, a fluorescent method, an optical method, and a piezoelectric method.

The biosensor is widely applied to a clinical field such as a sensor for measuring blood sugar level, as well as an environmental field of measuring phenol, heavy metals, agricultural chemicals, inflammable materials, and nitrogenous compounds in a waste water, a military field, an industrial field, and a sensor for research or the like.

Generally, a method of converting signals to detect biomaterials can be roughly classified into an electrochemical method and an optical method. In the electrochemical method, since a signal from the biomaterial should be converted into an electrical signal, the biosensor is too complicated to construct, and a production cost of an apparatus is increased. On the other hand, in the optical method, the biosensor can be more easily constructed than in the electrochemical method due to analyzing existence of a biomaterial by converting a signal from the biomaterial into an optical signal. Therefore, the optical method is widely used for a biosensor.

As a typical application of the optical method, there is an optical biosensor. The optical biosensor quantitatively measures the number of antigens based on fluorescence intensity from the sensor by labeling an antibody with a fluorescent material and detecting the antigen corresponding to the antibody.

In addition, currently as label-free biosensor shaving no a label material such as a fluorescent material, an optical biosensor such as a surface plasmon biosensor, a total internal reflection ellipsometry biosensor, and a waveguide biosensor have been developed.

The optical biosensor includes a light source generating light, a reaction unit where the antibody reacts with the antigen, and a detector detecting a light signal. As the light source, a light emitting diode and a laser are used. As the detector detecting a light, a spectrometer is used.

Generally, in the optical biosensor, the light source generating light is constructed with a gallium arsenide (GaAs)-based or a gallium nitride (GaN)-based compound semiconductor thin film layer.

However, in a case where the light source is constructed with the GaAs-based or GaN-based compound semiconductor thin film layer, it becomes difficult to grow a compound semiconductor thin film layer with a good quality on a substrate, and the costs of the substrate and source gas for growing the compound semiconductor thin film layer are increased.

In other words, a production cost of the light source for a conventional optical biosensor is increased.

In addition, since the compound semiconductor thin film layer used for manufacturing the light source for the conventional optical biosensor is mainly grown on a non-silicon-based substrate, the conventional optical sensor cannot be easily integrated or bonded with a silicon-based electronic device, so that it is difficult to manufacture the biosensor with a low price under mass production.

Moreover, in case of the optical biosensor includes the light source and the spectrometer as the detector, since the detector is very sensitive to a light direction in which the light source is incident into the reaction unit where the antibody reacts with the antigen, a complicated optical system is required for the optical biosensor.

### DISCLOSURE OF INVENTION

### Technical Problem

In order to solve conventional problems in that a production cost is increased, a silicon biosensor cannot be easily integrated or bonded with a silicon-based electronic device, and a complicated optical system is additionally required for the silicon biosensor, the present invention provides a silicon biosensor and a manufacturing method thereof, which decrease the production cost, can easily integrate or bond the silicon biosensor with the silicon-based electronic device, and is not required for the separate complicated optical system.

### Technical Solution

According to an aspect of the present invention, there is a silicon biosensor including: a light source performing self emission; a light detector generating a photoelectric current corresponding to an amount of incident light; an optical fiber transmitting the light from the light source to the light detector; and a micro fluidic channel adjusting an optical transmission rate of the optical fiber according to an antibody-antigen reaction when the antibody-antigen reaction occurs.

In addition, the light source may include: a hole-doped layer formed on an upper surface of a silicon substrate a light-emitting layer formed on an upper surface of the hole-doped layer and an electron-doped layer formed on an upper surface of the light-emitting layer. In addition, the light-emitting layer may be made of a silicon nitride (SiN) and the electron-doped layer and the hole-doped layer are constructed with silicon carbide-based films which have complementary polarities.

In addition, the light detector may include: a hole-doped layer formed on an upper surface of a silicon substrate a thin film layer formed on an upper surface of the hole-doped layer and an electron-doped layer formed on an upper surface of the thin film layer. In addition, the thin film layer may be made of a silicon nitride (SiN), and the electron-doped layer and the hole-doped layer may be constructed with silicon carbide-based films which have complementary polarities.

In addition, the silicon biosensor of the present invention may further include an insulator formed between the light source and the light detector to spatially separate the light source from the light detector. In addition, the optical fiber may be formed on an upper surface of the insulator and connect the light source to the light detector. In addition, the optical fiber may be formed by using the silicon nitride-based film.

In addition, the micro fluidic channel may be formed on an upper surface of the optical fiber. In addition, the micro fluidic channel may be made of polydimethylsiloxane (PDMS).

According to another aspect of the present invention, there is a method of manufacturing a silicon biosensor, including: sequentially depositing a first silicon film, a silicon nanocrystal, and a second silicon film on an upper surface of a silicon substrate; separating the first silicon film, the silicon nanocrystal, and the second silicon film into two regions by using an insultor forming a light source with the first silicon film, the silicon nanocrystal, and the second silicon film layered on one side of the insulator and forming a light detector with the first silicon film, the silicon nanocrystal, and the second silicon film on the remaining side of the insulator forming an optical fiber on an upper surface of the insulator and forming a micro fluidic channel on an upper surface of the optical fiber.

In addition, the silicon nanocrystal may be made of a silicon nitride (SiN), and the first and the second silicon film may be constructed with silicon carbide-based films which have complementary polarities.

In addition, the optical fiber may be formed by using a silicon nitride-based film. In addition, the micro fluidic channel may be made of PDMS.

### Advantageous Effects

According to the present invention, since a light source and a light detector are integrated on one silicon substrate, a production cost can be decreased, and the silicon biosensor can be easily integrated or bonded with a silicon-based electronic device.

In addition, according to the present invention, since a silicon biosensor is easily constructed with a light source and a detector as an optical system, an additional optical system is not needed, so that the biosensor can be manufactured with a low price under mass production.

### BRIEF DESCRIPTION OF THE DRAWINGS

FIG. 1 is a cross-sectional view illustrating a structure of a silicon biosensor according to an embodiment of the present invention.

FIGS. 2 to 4 are views illustrating operations of the silicon biosensor of FIG. 1.

FIGS. 5 to 8 are views illustrating a method of manufacturing a silicon biosensor according to an embodiment of the present invention.

### BEST MODE FOR CARRYING OUT THE INVENTION

Hereinafter, the present invention will now be described in detail with reference to the accompanying drawings, in which exemplary embodiments of the invention are provided so that the invention can be implemented by those skilled in the art. However, for clarifying the present invention, description of well-known functions and constructions will be omitted.

In addition, in the drawings, the same functions and operations are denoted by the same reference numerals.

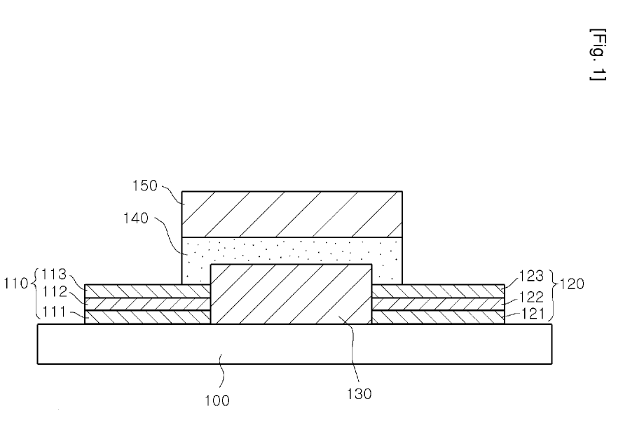

FIG. 1 is a cross-sectional view illustrating a structure of a silicon biosensor according to one exemplary embodiment of the present invention.

Referring to FIG. 1, a silicon biosensor includes a light source 110 emitting light, a light detector 120 generating a photoelectric current corresponding to an amount of incident light, an insulator 130 spatially separating the light source 110 from the light detector 120, an optical fiber 140 transmitting the light from the light source 110 to the light detector 120, and a micro fluidic channel 150 adjusting an optical transmission rate of the optical fiber according to an antibody-antigen reaction when the antibody-antigen reaction occurs.

The light source 110 is formed on one side of an upper surface of a silicon substrate 100, and the light detector 120 is formed on the other side of the upper surface of the silicon substrate 100. The insulator 130 is formed on the upper surface of the silicon substrate 100 between the insulator 130 and the light source 110, and the optical fiber 140 is formed on an upper surface of the insulator 130 to connect between the light source 110 and the light detector 120. The micro fluidic channel 150 is formed on an upper surface of the optical fiber 140.

In addition, the light source 110 includes a hole-doped layer 111 formed on the upper surface of the silicon substrate 100, a light-emitting layer 112 formed on an upper surface of the hole-doped layer 111, and an electron-doped layer 113 formed on an upper surface of the light-emitting layer 112.

The light detector 120 includes a hole-doped layer 121 formed on the upper surface of the silicon substrate 100, a thin film layer 122 formed on an upper surface of the hole-doped layer 121, and an electron-doped layer 123 formed on an upper surface of the thin film layer 122.

Although the light source 110 and the light detector 120 have similar layered structures, voltages are applied in different directions so that the light source 110 and the light detector 120 have different functions.

That is, the light source 110 is applied with a forward biased voltage through the electron-doped layer 113 and the hole-doped layer 111 to generate electron-hole couples occurs in the light-emitting layer 112. Therefore, the light is emitted. On the contrary, the light detector 120 is applied with a reverse biased voltage through the hole-doped layer 121 and the electron-doped layer 123 to absorb light from the light source 110, and so that the electron-hole couples in the thin film layer 122 are decoupled to generate a photoelectric current corresponding to an amount of incident light through the optical fiber 140.

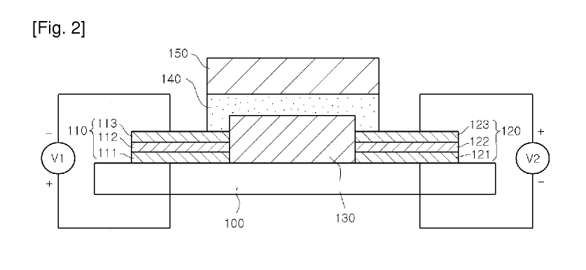

FIGS. 2 to 4 are views illustrating operations of the silicon biosensor of FIG. 1.

Firstly, as shown in FIG. 2, the light source 110 is applied with a forward biased voltage V1 to perform self emission, and the light detector 120 is applied with a reverse biased voltage V2 to perform light detection.

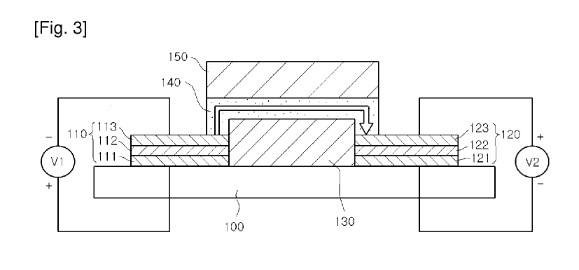

Then, as shown in FIG. 3, light is emitted by electron-hole couples in the light-emitting layer 112 of the light source 110. The light from the light source 110 is introduced into the optical fiber 140.

On the contrary, the thin film layer 122 of the light detector 120 absorbs the incident light through the optical fiber 140, so that the light detector 120 generates a photoelectric current having a value corresponding to an amount of the absorbed light when the electron-hole couples are decoupled.

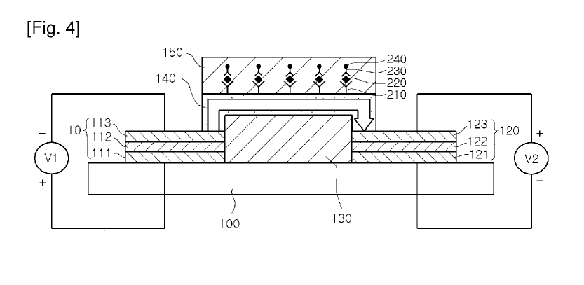

In this state, as shown in FIG. 4, the micro fluidic channel 150 is sequentially injected with a first bio antibody 210, a bio antigen 220, and a gold particle 240 attached with a second bio antibody 230.

Since the gold particle 240 has a very high light absorption coefficient, the amount of the light introduced from the optical fiber 140 to the light detector 120 is decreased by absorbing the light emitted from the light source 110.

For this reason, an antibody-antigen reaction occurs among the first bio antibody 210, the bio antigen 220, and the second bio antibody 230 in the micro fluidic channel 150, so that the amount of the light introduced to the light detector 120 is decreased.

Since the light is absorbed in the micro fluidic channel 150 due to the antibody-antigen reaction in the micro fluidic channel 150, the optical fiber 140 transfers a little amount of the light to the light detector 120. The light detector 120 generates the photoelectric current having a reduced value according to the reduced amount of the light.

As a result, values of the photoelectric current generated from the light detector 120 before and after the antibody-antigen reaction are different from each other.

For this reason, the number or existence of biomaterials, that is, the bio antigens, can be checked by analyzing the value of photoelectric current generated from the light detector 120.

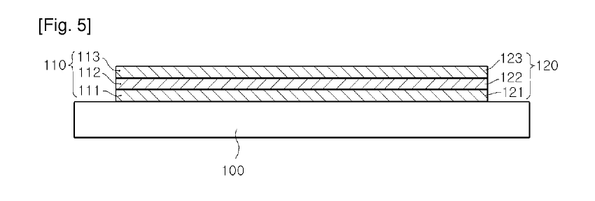

FIGS. 5 to 8 are views illustrating a method of manufacturing a silicon biosensor according to an embodiment of the present invention.

A biosensor according to the present invention will be constructed by using the silicon substrate 100. In a case of using the silicon substrate 100, the biosensor can be easily integrated or bonded with a silicon-based electronic device. In addition, since the costs of the silicon substrate 100 and source gas are reduced, the biosensor can be produced with a low price.

As shown in FIG. 5, p-type silicon films 111 and 121, silicon nanocrystals 112 and 122, and n-type silicon films 113 and 123 are sequentially deposited on an upper surface of the silicon substrate 100.

Preferably, the p-type silicon films 111 and 121 and the n-type silicon films 113 and 123 are constructed with silicon carbide-based films such as SiC or SiCN film. The silicon nanocrystals 112 and 122 are made of a silicon nitride (SiN).

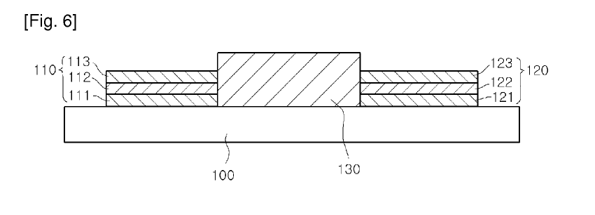

As shown in FIG. 6, central portions of the p-type silicon films 111 and 121, the silicon nanocrystals 112 and 122, and the n-type silicon films 113 and 123 are etched. After that, the etched central portion is deposited with silicon oxide (SiO₂) to form an insulator 130.

Therefore, the p-type silicon film 111, the silicon nanocrystal 112, and the n-type silicon film 113 layered on one side of the insulator 130 become a hole-doped layer 111, a light-emitting layer 112, and an electron-doped layer 113 of the light source 110, respectively. The p-type silicon film 120, the silicon nanocrystal 122, and the n-type silicon film 123 layered on the other side of the insulator 130 become a hole-doped layer 121, a thin film layer 122, and an electron-doped layer 123 of the light detector 120, respectively.

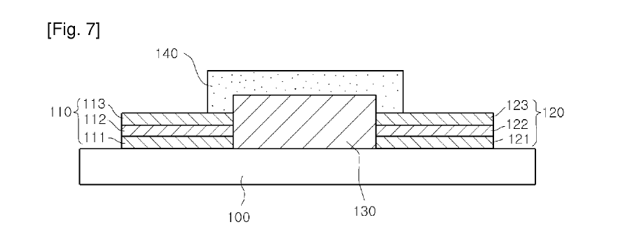

In addition, as shown in FIG. 7, an optical fiber 140 is formed on an upper portion of the insulator 130 by depositing a silicon nitride film to be commonly connected to the light source 110 and the light detector 120.

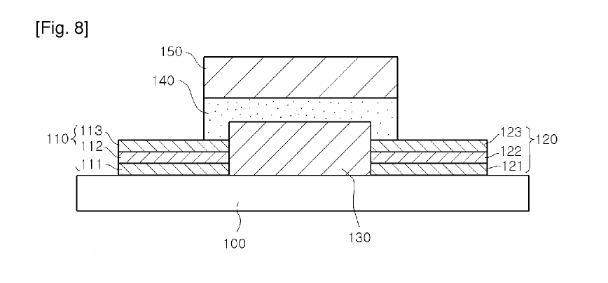

Finally, as shown in FIG. 8, a micro fluidic channel 150 is formed on an upper portion of the optical fiber 140 by using polydimethylsiloxane (PDMS).

The above-mentioned present invention is no limited to earlier described embodiments and attached drawings, it will be apparent to those skilled in the art from this disclosure that various changes and modifications can be made herein without departing from the scope of the invention.

1. A silicon biosensor comprising:
a light source performing self emission;
a light detector generating a photoelectric current corresponding to an amount of incident light;
an optical fiber transmitting the light from the light source to the light detector; and
a micro fluidic channel adjusting an optical transmission rate of the optical fiber according to an antibody-antigen reaction when the antibody-antigen reaction occurs.

2. The silicon biosensor of claim 1, wherein the light source comprises:
a hole-doped layer formed on an upper surface of a silicon substrate;
a light-emitting layer formed on an upper surface of the hole-doped layer; and
an electron-doped layer formed on an upper surface of the light-emitting layer.

3. The silicon biosensor of claim 2,
wherein the light-emitting layer is made of a silicon nitride (SiN), and
wherein the electron-doped layer and the hole-doped layer are constructed with silicon carbide-based films which have complementary polarities.

4. The silicon biosensor of claim 2, wherein the light detector comprises:
a hole-doped layer formed on an upper surface of a silicon substrate;
a thin film layer formed on an upper surface of the hole-doped layer; and
an electron-doped layer formed on an upper surface of the thin film layer.

5. The silicon biosensor of claim 4,
wherein the thin film layer is made of a silicon nitride (SiN), and
wherein the electron-doped layer and the hole-doped layer are constructed with silicon carbide-based films which have complementary polarities.

6. The silicon biosensor of claim 1, wherein the silicon biosensor further comprises an insulator formed between the light source and the light detector to spatially separate the light source from the light detector.

7. The silicon biosensor of claim 6, wherein the optical fiber is formed on an upper surface of the insulator and connects the light source to the light detector.

8. The silicon biosensor of claim 7, wherein the optical fiber is formed by using the silicon nitride-based film.

9. The silicon biosensor of claim 6, wherein the micro fluidic channel is formed on an upper surface of the optical fiber.

10. The silicon biosensor of claim 9, wherein the micro fluidic channel is made of PDMS (polydimethylsiloxane).

11. A method of manufacturing a silicon biosensor, the method comprising:
sequentially depositing a first silicon film, a silicon nanocrystal, and a second silicon film on an upper surface of a silicon substrate;
separating the first silicon film, the silicon nanocrystal, and the second silicon film into two regions by using an insulator
forming a light source with the first silicon film, the silicon nanocrystal, and the second silicon film layered on one side of the insulator, and forming a light detector with the first silicon film, the silicon nanocrystal, and the second silicon film on the remaining side of the insulator
forming an optical fiber on an upper surface of the insulator and
forming a micro fluidic channel on an upper surface of the optical fiber.

12. The method of claim 11,
wherein the silicon nanocrystal is made of a silicon nitride (SiN), and
wherein the first and the second silicon film are constructed with silicon carbide-based films which have complementary polarities.

13. The method of claim 11, wherein the optical fiber is formed by using a silicon nitride-based film.

14. The method of claim 11, wherein the micro fluidic channel is made of PDMS.
